(19) United States
(12) Patent Application Publication
(10) Pub. No.: US 2014/0151748 A1
(43) Pub. Date: Jun. 5, 2014

(54) COMPOUND SEMICONDUCTOR DEVICE AND MANUFACTURING METHOD OF THE SAME

(71) Applicant: Fujitsu Limited, Kawasaki-shi (JP)

(72) Inventors: Masato Nishimori, Atsugi (JP); Tadahiro Imada, Kawasaki (JP); Toshihiro Ohki, Hadano (JP)

(73) Assignee: Fujitsu Limited, Kawasaki-shi (JP)

(21) Appl. No.: 14/066,025

(22) Filed: Oct. 29, 2013

(30) Foreign Application Priority Data
Dec. 4, 2012 (JP) 2012-265499

(51) Int. Cl. H01L 29/778; H01L 29/66

(52) U.S. Cl. CPC H01L 29/778; H01L 29/66431; H01L 29/66462
USPC 257/194; 438/172

(57) ABSTRACT

The compound semiconductor device includes a first-compound-semiconductor-layer, a second-compound-semiconductor-layer formed on an upper side of the first-compound-semiconductor-layer and having a band gap larger than the band gap of the first-compound-semiconductor-layer, a p-type third-compound-semiconductor-layer formed on an upper side of the second-compound-semiconductor-layer, an electrode formed on an upper side of the second-compound-semiconductor-layer through the third-compound-semiconductor-layer, a fourth-compound-semiconductor-layer formed so as to be in contact with the third-compound-semiconductor-layer at an upper side of the second-compound-semiconductor-layer and having a band gap smaller than the band gap of the second-compound-semiconductor-layer, and a fifth-compound-semiconductor-layer formed so as to be in contact with the third-compound-semiconductor-layer at an upper side of the fourth-compound-semiconductor-layer and having a band gap larger than the band gap of the fourth-compound-semiconductor-layer.

### CROSS-REFERENCE TO RELATED APPLICATION

This application is based upon and claims the benefit of priority from the prior Japanese Patent Application No. 2012-265499 filed on Dec. 4, 2012, the entire contents of which are incorporated herein by reference.

### FIELD

The present invention relates to a compound semiconductor device and a manufacturing method of the same.

### BACKGROUND

A nitride semiconductor has been considered to be applied to a semiconductor device with high withstand voltage and high output, utilizing the characteristics of the nitride semiconductor such as high saturation electron speed and wide band gap. For example, the band gap of GaN which is a nitride semiconductor is 3.4 eV, which is larger than the band gap of Si (1.1 eV) and the band gap of GaAs (1.4 eV), and thus GaN has high breakdown electric field intensity. For that reason, GaN is quite promising as a material of a semiconductor device for power supply which requires a high voltage operation and high output.

As a semiconductor device using the nitride semiconductor, there have been numerous reports on a field effect transistor, particularly a high electron mobility transistor (HEMT). For example, among GaN-based HEMTs (GaN-HEMTs), AlGaN/GaN.HEMT using GaN as an electron transit layer and AlGaN as an electron supply layer is attracting attention. In the AlGaN/GaN.HEMT, a strain (e.g., a distortion) occurs in AlGaN resulting from the lattice constant difference between GaN and AlGaN. A two-dimensional electron gas (2DEG) of high concentration is obtained from piezoelectric polarization caused by the strain and spontaneous polarization of AlGaN. For that reason, for example, the AlGaN/GaN.HEMT is expected as a material for a high efficiency switch device and a high withstand voltage electric power device for electric vehicle. See, for example, Japanese Laid-Open Patent Publication No. 2009-76845, Japanese Patent Application Laid-Open No. 2007-19309, Japanese Laid-Open Patent Publication No. 2010-225765 and Japanese Laid-Open Patent Publication No. 2009-71061.

In general, a switching device for electric power requires a so-called a normally-off operation in which no current flows in the device, when the gate voltage thereof is 0 V. However, there is a problem in that a 2DEG with a high concentration is generated in the GaN-HEMT, and thus it is difficult to realize a normally-off type transistor. In order to address the problem, studies have been conducted in which the normally-off state is realized by etching an electron supply layer immediately below a gate electrode to decrease the concentration of the 2DEG. See, for example, Japanese Patent Application Laid-Open No. 2009-76845. However, in this technique, since a damage caused by etching occurs in the vicinity of an electron transit layer disposed below the electron supply layer, problems such as an increase in sheet resistance and leakage current occur. Therefore, in the AlGaN/GaN.HEMT, there has been proposed a technology in which the normally-off is realized by offsetting the 2DEG immediately below the gate electrode by additionally forming a conductive p-type GaN layer between the gate electrode and the active region. See, for example, Japanese Patent Application Laid-Open No. 2007-19309.

FIG. 1 illustrates a schematic configuration of a AlGaN/GaN.HEMT according to the aforementioned related art. In the AlGaN/GaN.HEMT, a nucleation layer is formed on a substrate, an electron transit layer 101 made of an i-GaN (e.g., an intentionally undoped layer) is formed thereon, and an electron supply layer 102 made of an i-AlGaN is formed thereon. The 2DEG is produced in the vicinity of the interface with the electron supply layer 102 of the electron transit layer 101. A p-type GaN layer 103 is formed on the electron supply layer 102, and a gate electrode 104 is formed thereon. On the electron supply layer 102, a source electrode 105 and a drain electrode 106 are formed at both sides of the gate electrode 104 (e.g. a p-type GaN layer 103).

When a voltage is not applied to the gate electrode 104, holes are localized in the p-type GaN layer 103 at the lower portion thereof (e.g., in the vicinity of the interface of the p-type GaN layer 103 with the electron supply layer 102). Electrons are attracted by the holes and induced in the vicinity of the interface of the electron transit layer 101 therebelow with the electron supply layer 102. Accordingly, the gate voltage Vg is turned on. As described above, there is a problem in that the normally-off is suppressed, and thus, the threshold voltage may not be increased.

### SUMMARY

An aspect of the compound semiconductor device includes a first compound semiconductor layer, a second compound semiconductor layer formed on an upper side of the first compound semiconductor layer and having a band gap larger than the band gap of the first compound semiconductor layer, a p-type third compound semiconductor layer formed on an upper side of the second compound semiconductor layer, an electrode formed on an upper side of the second compound semiconductor layer through the third compound semiconductor layer, a fourth compound semiconductor layer formed so as to be in contact with the third compound semiconductor layer at an upper side of the second compound semiconductor layer and having a band gap smaller than the band gap of the second compound semiconductor layer, and a fifth compound semiconductor layer formed so as to be in contact with the third compound semiconductor layer at an upper side of the fourth compound semiconductor layer and having a band gap larger than the band gap of the fourth compound semiconductor layer.

An aspect of the method for manufacturing a compound semiconductor device includes a process of forming a second compound semiconductor layer having a band gap larger than the band gap of a first compound semiconductor layer on an upper side of the first compound semiconductor layer, a process of forming a p-type third compound semiconductor layer on an upper side of the second compound semiconductor layer, a process of forming an electrode on an upper side of the second compound semiconductor layer through the third compound semiconductor layer, a process of forming a fourth compound semiconductor layer having a band gap smaller than the band gap of the second compound semiconductor layer so as to be in contact with the third compound semiconductor layer at an upper side of the second compound semiconductor layer, and a process of forming a fifth compound semiconductor layer having a band gap larger than the band gap of the fourth compound semiconductor layer so as to be in contact with the third compound semiconductor layer at an upper side of the fourth compound semiconductor layer.

The object and advantages of the invention will be realized and attained by means of the devices and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a schematic cross-sectional view illustrating a schematic configuration of an AlGaN/GaN.HEMT in the related art.

FIGS. 2A-2C are schematic cross-sectional views illustrating a manufacturing method of the AlGaN/GaN.HEMT according to a first exemplary embodiment in a process sequence.

FIGS. 3A-3B are schematic cross-sectional views illustrating the manufacturing method of the AlGaN/GaN.HEMT according to the first exemplary embodiment in a process sequence subsequent to FIGS. 2A-2C.

FIG. 4 is a schematic cross-sectional view illustrating each compound semiconductor layer of the AlGaN/GaN.HEMT according to the first exemplary embodiment.

FIG. 5 is a characteristic view illustrating a band gap of each compound semiconductor layer of the AlGaN/GaN.HEMT according to the first exemplary embodiment.

FIG. 6 is a schematic cross-sectional view for describing the function of the AlGaN/GaN.HEMT according to the first exemplary embodiment.

FIGS. 7A-7B are characteristic views illustrating the relationship between gate voltage Vd and drain current Id based on the comparison with the AlGaN/GaN.HEMT in Comparative Example with respect to the AlGaN/GaN.HEMT according to the first exemplary embodiment.

FIGS. 8A-8C are schematic cross-sectional views illustrating a manufacturing method of the AlGaN/GaN.HEMT according to a second exemplary embodiment in a process sequence.

FIGS. 9A-9B are schematic cross-sectional views illustrating a manufacturing method of the AlGaN/GaN.HEMT according to the second exemplary embodiment in a process sequence subsequent to FIGS. 8A-8 C.

FIGS. 10A-10C are schematic cross-sectional views illustrating a manufacturing method of the AlGaN/GaN.HEMT according to a third exemplary embodiment in a process sequence.

FIGS. 11A-11B are schematic cross-sectional views illustrating a manufacturing method of the AlGaN/GaN.HEMT according to the third exemplary embodiment in a process sequence subsequent to FIGS. 10 A-10C.

FIGS. 12A-12C are schematic cross-sectional views illustrating a manufacturing method of the AlGaN/GaN.HEMT according to a fourth exemplary embodiment in a process sequence.

FIGS. 13A-13C are schematic cross-sectional views illustrating a manufacturing method of the AlGaN/GaN.HEMT according to the fourth exemplary embodiment in a process sequence subsequent to FIGS. 12 A-12C.

FIG. 14 is a connection diagram illustrating a schematic configuration of a power supply according to the fourth exemplary embodiment.

FIG. 15 is a connection diagram illustrating a schematic configuration of a high frequency amplifier according to a fifth embodiment.

### DESCRIPTION OF EMBODIMENTS

### First Exemplary Embodiment

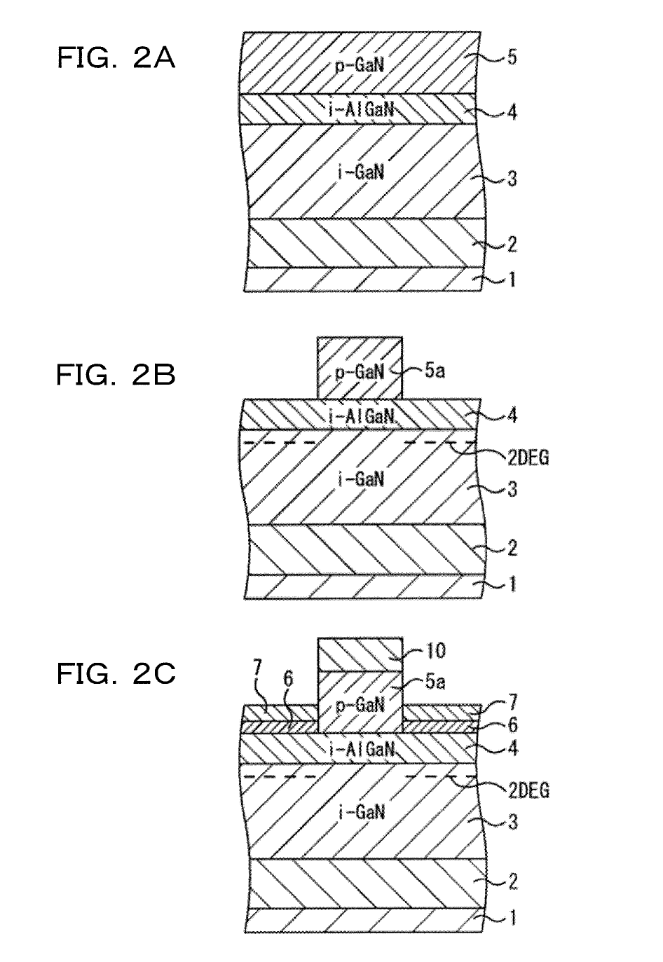

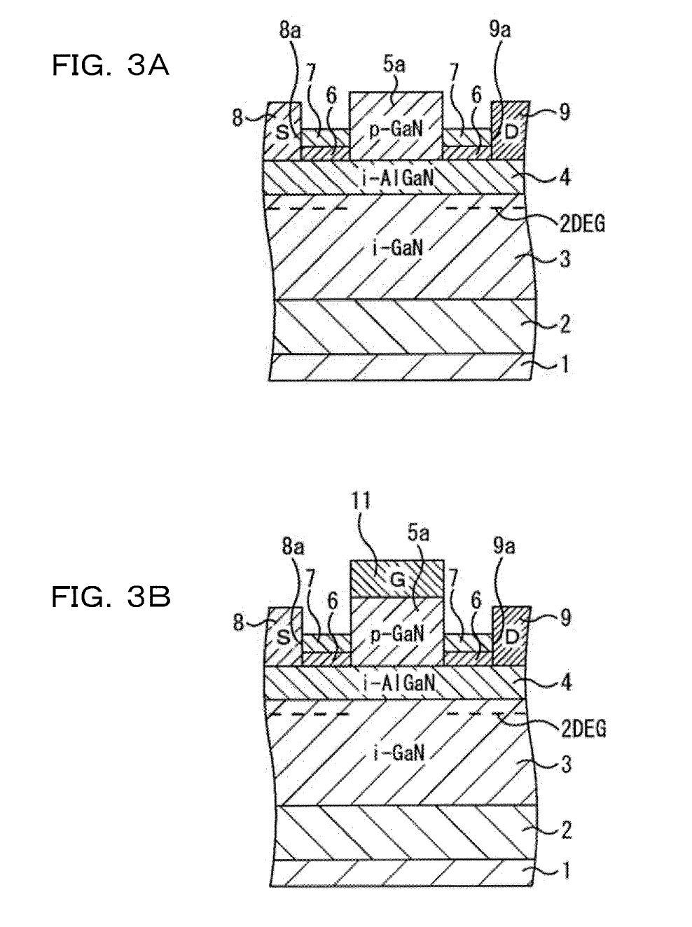

The present embodiment discloses the AlGaN/GaN.HEMT of a nitride semiconductor as a compound semiconductor device. FIGS. 2A to 2C and 3A to 3B are schematic cross-sectional views illustrating a manufacturing method of the AlGaN/GaN.HEMT according to a first exemplary embodiment in a process sequence.

As illustrated in FIG. 2A, a buffer layer 2, an electron transit layer 3, an electron supply layer 4, and a p-type GaN layer 5 are sequentially formed on, for example, an SiC substrate 1 serving as a growth substrate. As the growth substrate, for example, a Si substrate, a sapphire substrate, a GaAs substrate, and a GaN substrate may be used instead of the SiC substrate. Further, for conductivity of the substrate, it does not matter whether the substrate is semi-insulating or conductive.

Specifically, each of the following compound semiconductors is grown on a SiC substrate 1 under a reduced pressure atmosphere by using, for example, a metal organic vapor phase epitaxy (MOVPE) method. Other method such as, for example, a molecular beam epitaxy (MBE) method may be used instead of the MOVPE method. On the SiC substrate 1, an AlN layer with a thickness of approximately 100 nm, an i-GaN layer with a thickness of approximately 3 μm, an i-AlGaN layer with a thickness of approximately 20 nm, and a p-GaN layer with a thickness of approximately 80 nm are sequentially grown. Accordingly, the buffer layer 2, the electron transit layer 3, the electron supply layer 4, and the p-type GaN layer 5 are formed.

The buffer layer 2 becomes a nucleation layer, and an AlGaN layer may be used instead of the AlN layer, or a GaN layer may be grown by low-temperature growth processes. The electron supply layer 4 is made of Al_{0.2}Ga_{0.8}N with an Al composition ratio of, for example, 0.2. An n-type AlGaN (n-AlGaN) layer may be formed instead of the i-AlGaN layer. A p-type AlGaN layer may be formed instead of a p-type GaN layer 5. A spacer layer may be formed between the electron transit layer 3 and the electron supply layer 4 as an intermediate layer.

As for the growth condition of the AlN layer, a mixed gas of a trimethylaluminum (TMAI) gas and an ammonia (NH₃) gas is used as a raw material gas. As for the growth condition of the GaN layer, a mixed gas of a trimethylgallium (TMG) gas and an NH₃ gas is used as a raw material gas. As for the growth condition of the AlGaN layer, a mixed gas of the TMA gas, the TMG gas, and the NH₃ gas is used as a raw material gas. The presence/absence of supply of and the flow rates of the trimethylaluminum gas as an Al source and the trimethylgallium gas as a Ga source are set appropriately depending on the compound semiconductor layer to be grown. The flow rate of the ammonia gas serving as a common raw material is set to approximately 100 ccm to 10 LM. In addition, the growth pressure is approximately 50 Torr to 300 Torr, and the growth temperature is set to approximately 1,000° C. to 1,200° C.

When the electron supply layer 4 is formed of n-AlGaN, for example, SiH₄ gas including Si as an n-type impurity is added to the raw material gas at a predetermined flow rate, so as to dope Si into AlGaN. The doping concentration of Si is set to approximately 1×10¹⁸/cm³ to approximately 1×10²⁰/cm³, for example, approximately 5×10¹⁸/cm³.

When the p-type GaN layer 5 is formed, for example, a cyclopentadienylmagnesium (CpMg) gas including, for example, the Mg ions serving as a p-type impurity may be introduced, so as to dope the Mg ions into GaN. The doping concentration of the Mg ions is set to approximately 1×10¹⁸/cm³ to approximately 1×10²⁰/cm³, for example, approximately 5×10¹⁸/cm³. Thereafter, the doped Mg ions are activated by subjecting the p-GaN to an annealing treatment, for example, at 800° C. for approximately 20 minutes.

Subsequently, as illustrated in FIG. 2B, the p-type GaN layer 5 is etched. Specifically, a resist is applied on the p-type GaN layer 5, and UV rays are irradiated on a portion other than a gate electrode formation scheduled region by using a predetermined mask. Accordingly, a resist mask is formed, which covers the gate electrode formation scheduled region of the p-type GaN layer 5 with the resist. The p-type GaN layer 5 is dry-etched by using the resist mask, and using a Cl₂-based etching gas. Accordingly, the p-type GaN layer 5 is remaining only in the gate electrode formation scheduled region. The remaining p-type GaN layer 5 is defined as a p-type GaN layer 5a. The resist mask is removed by an ashing treatment or a chemical treatment.

Subsequently, as illustrated in FIG. 2C, an i-GaN layer 6 and an i-AlGaN layer 7 are sequentially formed on an electron supply layer 4 at both sides of the p-type GaN layer 5a. Specifically, a predetermined resist mask is formed first, and for example, SiO₂ is deposited thereon by, for example, a CVD method, so as to form a mask layer 10 which covers the top of the p-type GaN layer 5a. Subsequently, i-GaN with a thickness of approximately 10 nm and i-AlGaN with a thickness of approximately 10 nm are sequentially grown on the electron supply layer 4 under a reduced pressure atmosphere by the MOVPE method. Accordingly, an i-GaN layer 6 and an i-AlGaN layer 7 are formed. The i-AlGaN layer 7 is made of i-Al_{0.2}Ga_{0.8}N with an Al composition ratio of, for example, 0.2. The mask layer 10 is removed by, for example, a chemical treatment.

Subsequently, a device isolation structure is formed. Specifically, for example, argon (Ar) is implanted into a device isolation region at the upper side of the SiC substrate 1. Accordingly, the device isolation structure is formed at surface layer portions of the i-AlGaN layer 7, the i-GaN layer 6, the electron supply layer 4, and the electron transit layer 3. By the device isolation structure, an active region is defined on the i-AlGaN layer 7. Alternatively, the device isolation may be performed using, for example, an STI (Shallow Trench Isolation) method instead of the aforementioned implanting method.

Subsequently, as illustrated in FIG. 3A, a source electrode 8 and a drain electrode 9 are formed. Specifically, electrode recesses 8a and 9a are formed first at electrode formation scheduled positions for the source electrode and the drain electrode in the surface of the i-AlGaN layer 7. A resist is applied on the entire surface thereof. The resist is processed by the lithography process and openings are formed in the resist, which expose the surface of the i-AlGaN layer 7 corresponding to the electrode formation scheduled positions. By the above process, a resist mask having the openings is formed.

Using the resist mask, the electrode formation scheduled positions of the i-AlGaN layer 7 and the i-GaN layer 6 are dry-etched and removed until the surface of the electron supply layer 4 is exposed. As a result, the electrode recesses 8a and 9a are formed, which expose the electrode formation scheduled positions of the surface of the electron supply layer 4. For example, Cl₂ gas may be used as an etching gas. Meanwhile, the electrode recesses 8a and 9a may be formed by etching to the middle of the i-AlGaN layer 7, or may be formed by etching beyond the surface of the electron supply layer 4. The resist mask is removed by, for example, an ashing treatment.

A resist mask for forming the source electrode and the drain electrode is formed. Here, for example, a two-layer resist with an eaves structure is used, which is suitable for a vapor deposition method and a lift-off method. This resist is applied on the entire surface thereof, and openings are formed for exposing the electrode recesses 8a and 9a. By the above process, a resist mask having the openings is formed.

Using the resist mask, for example, a Ti/Al layer is deposited as an electrode material by, for example, a vapor deposition method, on the resist mask including the openings for exposing the electrode recesses 8a and 9a. The thickness of the Ti layer is set to approximately 20 nm, and the thickness of the Al layer is set to approximately 200 nm. The resist mask and the Ti/Al layer deposited thereon are removed by, for example, the lift-off method. Thereafter, the SiC substrate 1 is thermally treated at a temperature of approximately 400° C. to 1,000° C., for example, approximately 550° C., for example, in a nitrogen atmosphere, so as to bring the remaining the Ti/Al layer into an ohmic contact with the electron supply layer 4. As long as an ohmic contact can be obtained with the electron supply layer 4 of Ti/Al, heat treatment may not be necessary. By the above process, the source electrode 8 and the drain electrode 9 are formed such that the electrode recesses 8a and 9a are embedded by a part of the electrode material.

Subsequently, as illustrated in FIG. 3B, a gate electrode 11 is formed. Specifically, a mask for forming the gate electrode is formed first. Here, for example, a SiN layer is deposited on the entire surface thereof by, for example, a CVD method, and dry-etching is performed by using, for example, a CF₄ gas, so as to form the openings in the SiN layer which expose the top of the p-type GaN layer 5a. By the above process, a mask having the openings is formed.

Using the mask, for example, an Ni/Au layer is deposited as an electrode material by, for example, a vapor deposition method, on the mask including the inner portion of the openings for exposing the top of the p-type GaN layer 5a. The thickness of the Ni layer is set to approximately 30 nm, and the thickness of the Au layer is set to approximately 400 nm. The mask and the Ni/Au layer deposited thereon are removed by, for example, the lift-off method. The mask may also be used as a protective film without being removed. By the above process, a gate electrode 11 is formed on the p-type GaN layer 5a.

Thereafter, going through various processes such as forming an interlayer dielectric, forming wirings connected to the source electrode 8, the drain electrode 9, and the gate electrode 11, forming the passivation film of the upper layer, and forming a connection electrode exposed to the outermost surface thereof, the AlGaN/GaN.HEMT according to the present embodiment is formed.

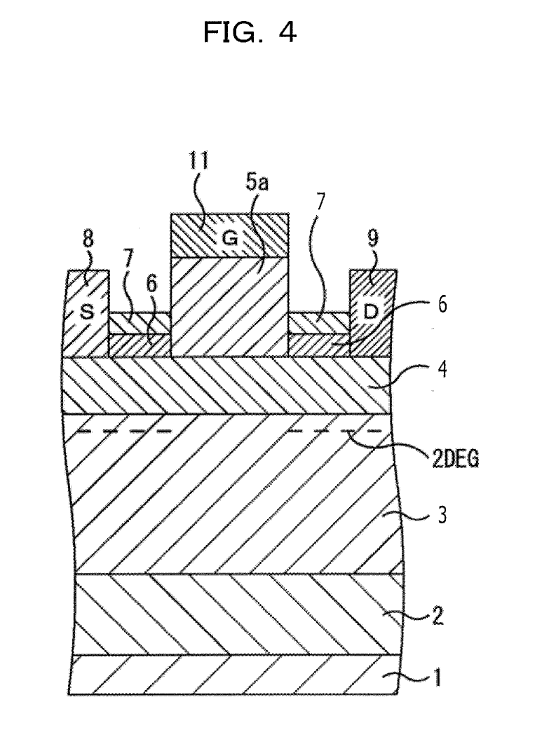

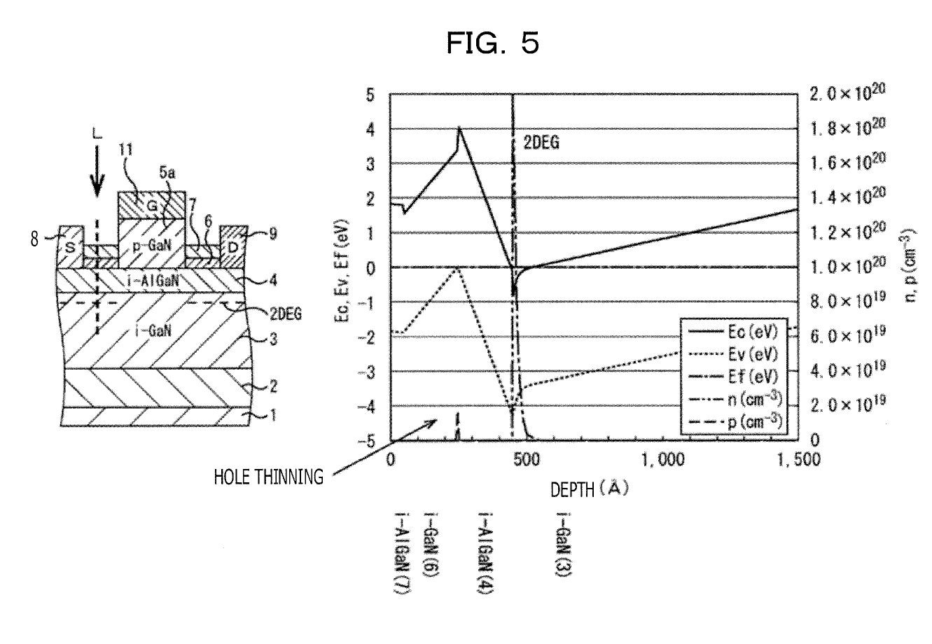

In the AlGaN/GaN.HEMT according to the present embodiment, the band gap of each compound semiconductor layer has characteristics. FIG. 4 corresponds to FIG. 3B, and is a schematic cross-sectional view illustrating each compound semiconductor layer of the AlGaN/GaN.HEMT according to the present embodiment. FIG. 5 is a characteristic view illustrating a band gap of each compound semiconductor layer of the AlGaN/GaN.HEMT according to the present embodiment, and corresponds to the cross-section along the broken line represented by the arrow L illustrated at the left.

The electron transit layer 3, the electron supply layer 4, the i-GaN layer 6, and the i-AlGaN layer 7 in FIG. 3B are specific examples of the first layer, the second layer, the third layer, and the fourth layer in FIG. 4. Meanwhile, the band gap in FIG. 5 is calculated by using a simulation that the electron supply layer 4 of the second layer is formed of i-Al_{0.3}Ga_{0.7}N with a thickness of 20 nm, the i-GaN layer 6 of the third layer has a thickness of 20 nm, the i-AlGaN layer 7 of the fourth layer is formed of i-Al_{0.15}Ga_{0.85}N with a thickness of 5 nm, and the p-type GaN layer 5a has a thickness of 60 nm. BG1, BG2, BG3, and BG4, which are band gaps of the first layer, the second layer, the third layer, and the fourth layer, satisfy the following relationships.

BG2>BG1 (1)

Further, BG2>BG3 (2)

In addition, BG4>BG3 (3)

It becomes a requirement for generating a two-dimensional electron gas (2DEG) to satisfy the relationship of Equation (1). That is, during the operation of the HEMT, the 2DEG occurs in the vicinity of the interface of the electron transit layer 3 with the electron supply layer 4 (e.g., an intermediate layer in the case of having the intermediate layer). The 2DEG is produced based on a lattice constant difference between the compound semiconductor of the electron transit layer 3 (e.g., a GaN layer) and the compound semiconductor of the electron supply layer 4 (e.g., a AlGaN layer). As illustrated in FIG. 5, it can be seen that a 2DEG (n/cm³) of high concentration is produced in the vicinity of the interface of the electron transit layer 3 with the electron supply layer 4 in order to satisfy the relationship of Equation (1).

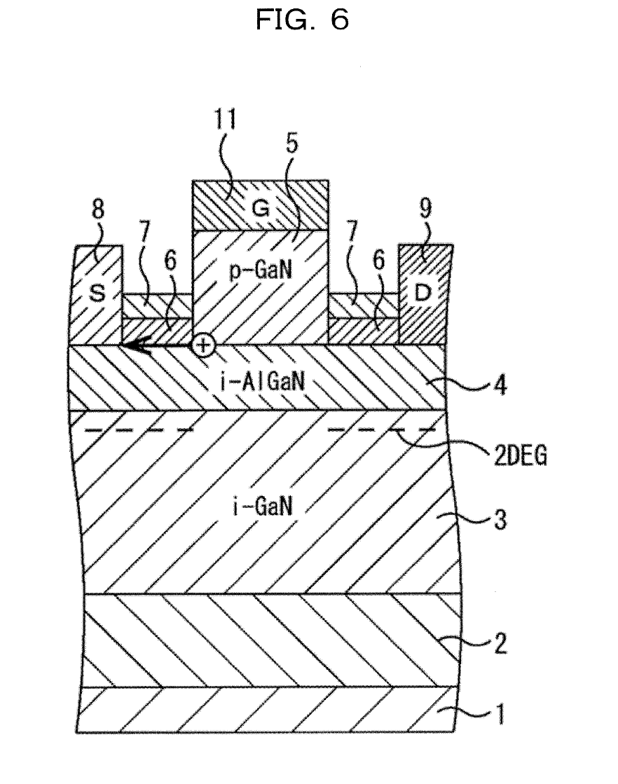

It becomes a requirement for generating holes in the vicinity of the interface between the electron supply layer 4 and the i-GaN layer 6 to satisfy the relationships of Equations (2) and (3). As illustrated in FIG. 6, this indicates that holes accumulated at the lower portion of the p-type GaN layer 5a pass the vicinity of the interface between the electron supply layer 4 and the i-GaN layer 6, and escape into the source electrode 8. As illustrated in FIG. 5, it can be seen that holes at a relatively high concentration are present in the vicinity of the interface between the electron supply layer 4 and the i-GaN layer 6 in order to satisfy the relationships of Equations (2) and (3).

In the AlGaN/GaN.HEMT according to the present embodiment, the first layer, the second layer, the third layer, and the fourth layer satisfy the relationships of Equations (1), (2), and (3). Accordingly, the first to fourth layers are not limited to the compound semiconductor layers illustrated in FIGS. 2A to 2C and 3A to 3B. For example, as the third layer, it is possible to use an AlGaN layer with an Al composition ratio smaller than the Al composition ratio of the electron supply layer 4 (e.g., 0.2 in the example of FIG. 3B, and 0.3 in the example of FIG. 4) and with an Al composition ratio smaller than the Al composition ratio of the i-AlGaN layer 7 (e.g., 0.2 in the example of FIG. 3B, and 0.15 in the example of FIG. 4) instead of the i-GaN layer 6. For example, Al_{0.05}Ga_{0.95}N with an Al composition ratio of 0.05 may be contemplated. It is also suitable for the p-type or n-type GaN layer to be used instead of the i-GaN layer 6. As the fourth layer, for example, the AlN layer may be used instead of the i-AlGaN layer 7.

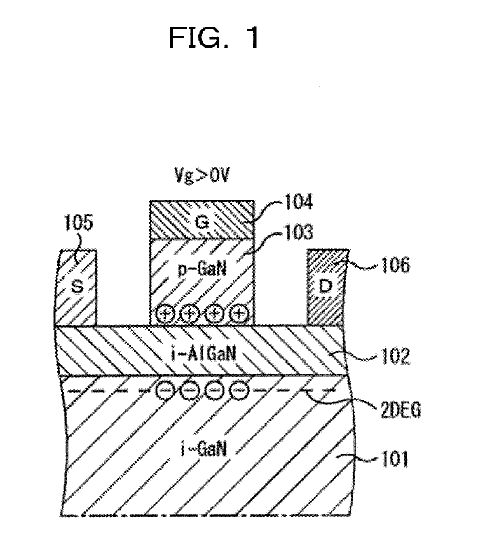

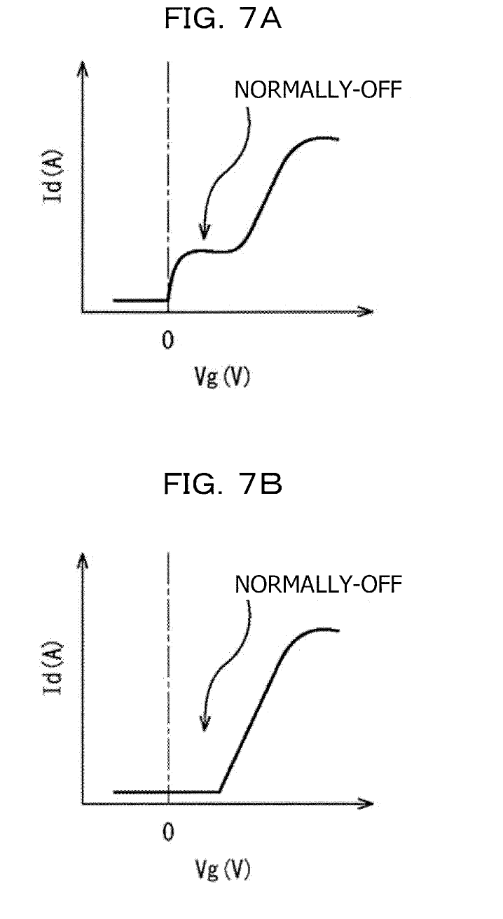

FIGS. 7A to 7B are characteristic views illustrating the relationship between a gate voltage Vd and drain current Id based on the comparison with the AlGaN/GaN.HEMT in Comparative Example with respect to the AlGaN/GaN.HEMT according to the present embodiment. FIG. 7A is a characteristic view of the AlGaN/GaN.HEMT illustrated in FIG. 1 as Comparative Example, and FIG. 7B is a characteristic view of the AlGaN/GaN.HEMT according to the present embodiment.

In Comparative Example, it can be seen that when a voltage is not applied to the gate electrode, the normally-on state becomes actuated at a value equal to or smaller than the threshold voltage by the localization of holes in the p-type GaN layer. In contrast, in the present embodiment, since there is no localization of holes in the p-type GaN layer, the normally-off state is realized. As described above, in the present embodiment, the localization of holes in the p-type GaN layer 5a is solved and a sufficiently large threshold voltage is obtained, thereby realizing the normally-off state.

Furthermore, the i-AlGaN layer 7 serves as a barrier layer for holes, and thus holes are suppressed from being trapped in, for example, a passivation film, which are film-formed on the i-AlGaN layer 7. Accordingly, the problem of operation instability due to a hole thinning is solved.

As described above, in the present embodiment, it is possible to obtain a highly-reliable high withstand voltage AlGaN/GaN.HEMT which has neither deterioration in withstand voltage nor operation instability with a relatively simple configuration, and obtains a sufficiently large threshold voltage, and thus certainly realizes the normally-off state.

### Second Exemplary Embodiment

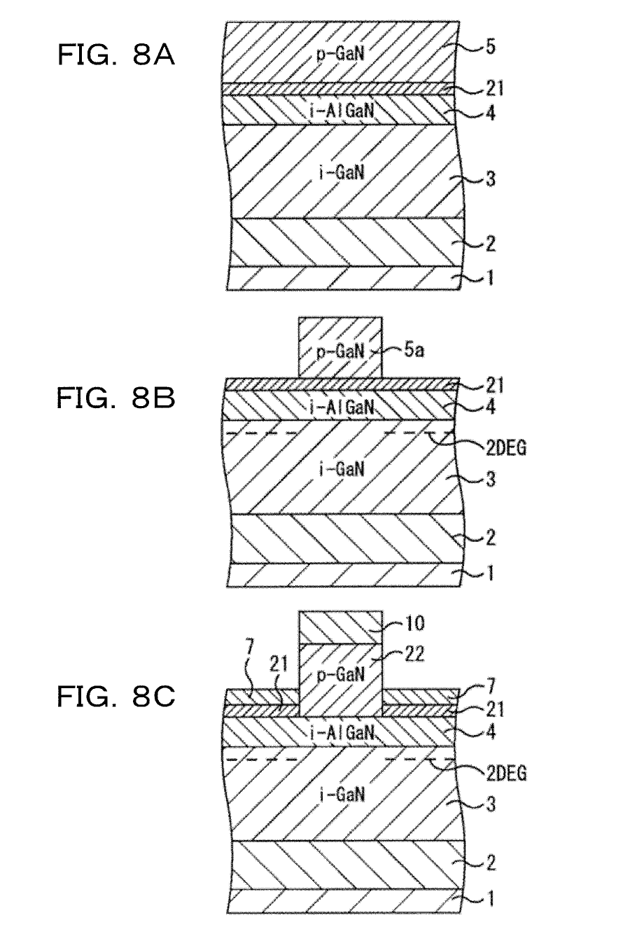

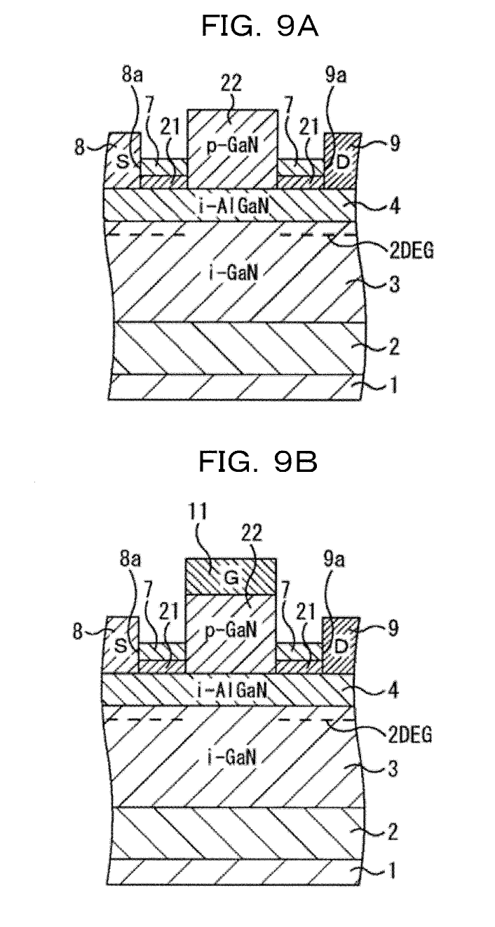

The present embodiment discloses a configuration and a manufacturing method of an AlGaN/GaN.HEMT in the same manner as in the first exemplary embodiment, but is different from the first exemplary embodiment in that the formation states of the i-GaN layer on the electron supply layer are different from each other. Meanwhile, the same numerals are given to the same constituent members as those in the first exemplary embodiment, and the detailed description thereof will be omitted. FIGS. 8A to 8C and 9A to 9B are schematic cross-sectional views illustrating a manufacturing method of the AlGaN/GaN.HEMT according to a second exemplary embodiment in a process sequence.

First, as illustrated in FIG. 8A, a buffer layer 2, an electron transit layer 3, an electron supply layer 4, an i-GaN layer 21, and a p-type GaN layer 5 are sequentially formed on, for example, a SiC substrate 1 serving as a growth substrate. Specifically, each of the following compound semiconductors is grown under a reduced pressure atmosphere in the growth conditions described in the first exemplary embodiment by an MOVPE method. For example, an MBE method may be used instead of the MOVPE method.

On the SiC substrate 1, an AlN layer with a thickness of approximately 100 nm, an i-GaN layer with a thickness of approximately 3 μm, an i-AlGaN layer with a thickness of approximately 20 nm, an i-GaN layer with a thickness of approximately 10 nm, and a p-GaN layer with a thickness of approximately 80 nm are sequentially grown. In the growth of the AlN layer, a mixed gas of a TMAI gas and the NH₃ gas is used as a raw material gas. In the growth of the i-GaN layer, a mixed gas of a TMG gas and the NH₃ gas is used as a raw material gas. In the growth of the i-AlGaN layer, a mixed gas of the TMG gas, the TMAI gas, and the NH₃ gas is used as a raw material gas. In the growth of the p-GaN layer, a mixed gas of the TMG gas and the NH₃ gas is used as a raw material gas, and for example, the CpMg gas including, for example, the Mg ions serving as a p-type impurity may be introduced. By the above processes, the buffer layer 2, the electron transit layer 3, the electron supply layer 4, the i-GaN layer 21, and the p-type GaN layer 5 are formed.

Subsequently, as illustrated in FIG. 8B, the p-type GaN layer 5 is etched. Specifically, a resist is applied on the p-type GaN layer 5, and UV rays are irradiated on a portion other than a gate electrode formation scheduled region by using a predetermined mask. As a result, a resist mask is formed, which covers the gate electrode formation scheduled region of the p-type GaN layer 5 with a resist. The p-type GaN layer 5 is dry-etched by using the resist mask, and using a Cl₂-based etching gas. As a result, the p-type GaN layer 5 remains only in the gate electrode formation scheduled region. The remaining p-type GaN layer 5 is defined as a p-type GaN layer 5a. The resist mask is then removed by, for example, an ashing treatment or a chemical treatment.

Subsequently, as illustrated in FIG. 8C, the AlGaN layer 7 is formed on an i-GaN layer 21 at both sides of the p-type GaN layer 5a. Specifically, a predetermined resist mask is formed, and for example, SiO₂ is deposited thereon by, for example, a CVD method, so as to form a mask layer 10 which covers the top of the p-type GaN layer 5a. Subsequently, the i-AlGaN layer with a thickness of approximately 10 nm is grown on the i-GaN layer 21 under a reduced pressure atmosphere by the MOVPE method, forming an i-AlGaN layer 7. The i-AlGaN layer 7 is made of i-Al_{0.2}Ga_{0.8}N with an Al composition ratio of, for example, 0.2.

In the present embodiment, during the formation of the i-AlGaN layer 7, the Mg ions contained in the p-type GaN layer 5a is diffused into the i-GaN layer 21 at the lower side by the high temperature formed when the i-AlGaN layer is grown. As a result, a region disposed under the p-type GaN layer 5a of the i-GaN layer 21 becomes p-type, and thus the region becomes a p-type GaN and is integrated with the p-type GaN layer 5a. The p-type GaN integrated with the p-type GaN layer is defined as a p-type GaN layer 22. Meanwhile, there may be cases where only a part of the region disposed under the p-type GaN layer 5a of the i-GaN layer 21 becomes p-type depending on the diffusion degree of the Mg ions of the p-type GaN layer 5a. The mask layer 10 is removed by, for example, a chemical treatment.

Subsequently, a device isolation structure is formed. Specifically, for example, argon (Ar) is implanted into a device isolation region at the upper side of the SiC substrate 1. As a result, the device isolation structure is formed at the surface layer portions of the AlGaN layer 7, the i-GaN layer 21, the electron supply layer 4, and the electron transit layer 3. By the device isolation structure, an active region is defined on the i-AlGaN layer 7. Alternatively, the device isolation may be performed using, for example, an STI method instead of the aforementioned implanting method.

Subsequently, as illustrated in FIG. 9A, a source electrode 8 and a drain electrode 9 are formed. Specifically, electrode recesses 8a and 9a are formed first at the electrode formation scheduled positions for the source electrode and the drain electrode in the surface of the i-AlGaN layer 7. A resist is applied on an exposed surface including the surface of the i-AlGaN layer 7. The resist is processed by the lithography process and openings are formed in the resist, which expose the surface of the i-AlGaN layer 7 corresponding to the electrode formation scheduled positions. By the above process, a resist mask having the openings is formed.

Using the resist mask, the electrode formation scheduled positions of the i-AlGaN layer 7 and the i-GaN layer 21 are dry-etched and removed until the surface of the electron supply layer 4 is exposed. As a result, the electrode recesses 8a and 9a are formed, which expose the electrode formation scheduled positions of the surface of the electron supply layer 4. For example, Cl₂ gas may be used as an etching gas. Meanwhile, the electrode recesses 8a and 9a may be formed by etching to the middle of the i-AlGaN layer 7, or may be formed by etching beyond the surface of the electron supply layer 4. The resist mask is removed by, for example, an ashing treatment.

A resist mask for forming the source electrode and the drain electrode is formed. Here, for example, a two-layer resist with an eaves structure may be used, which is suitable for a vapor deposition method and a lift-off method. This resist is applied on an exposed surface including the surface of the AlGaN layer 7, and openings for exposing the electrode recesses 8a and 9a are formed. By the above process, a resist mask having the openings is formed.

Using this resist mask, for example, the Ti/Al layer is deposited as an electrode material by, for example, a vapor deposition method, on the resist mask including the inner portion of the openings for exposing the electrode recesses 8a and 9a. The thickness of the Ti layer is set to approximately 20 nm, and the thickness of the Al layer is set to approximately 200 nm. The resist mask and the Ti/Al layer deposited thereon are removed by, for example, the lift-off method. Thereafter, the SiC substrate 1 is thermally treated at a temperature of approximately 400° C. to 1,000° C., for example, approximately 550° C., for example, in a nitrogen atmosphere, so as to bring the remaining Ti/Al layer into an ohmic contact with the electron supply layer 4. As long as an ohmic contact can be obtained with the electron supply layer 4 of the Ti/Al layer, heat treatment may not be necessary. By the above process, the source electrode 8 and the drain electrode 9 are formed such that the electrode recesses 8a and 9a are embedded by a part of the electrode material.

Subsequently, as illustrated in FIG. 9B, a gate electrode 11 is formed. Specifically, a mask for forming the gate electrode is formed first. Here, for example, SiN is deposited on the entire surface thereof by, for example, a CVD method, and dry-etching is performed by using, for example, a CF₄ gas, so as to form openings which expose the top of the p-type GaN layer 22 to SiN. By the above process, a mask having the openings is formed.

Using the mask, for example, a Ni/Au layer is deposited as an electrode material by, for example, a vapor deposition method, on the mask including the inner portion of the openings for exposing the top of the p-type GaN layer 22. The thickness of the Ni layer is set to approximately 30 nm, and the thickness of the Au layer is set to approximately 400 nm. The mask and the Ni/Au layer deposited thereon may be removed by, for example, the lift-off method. The mask may also be used as a protective film without being removed. By the above process, a gate electrode 11 is formed on the p-type GaN layer 22.

Thereafter, going through various processes such as forming an interlayer dielectric, forming wirings connected to the source electrode 8, the drain electrode 9, and the gate electrode 11, forming the passivation film of the upper layer, and forming a connection electrode exposed to the outermost surface thereof, the AlGaN/GaN.HEMT according to the present embodiment is formed.

As described above, in the present embodiment, it is possible to obtain a highly-reliable high withstand voltage AlGaN/GaN.HEMT which has neither deterioration in withstand voltage nor operation instability with a relatively simple configuration, and obtains a sufficiently large threshold voltage, and thus certainly realizes the normally-off state.

Furthermore, in the present embodiment, an i-GaN layer 21 is formed between the electron supply layer 4 and the p-type GaN layer 5. That is, the i-GaN layer 21 is present immediately below the p-type GaN layer 5. For that reason, during the activation annealing of the p-type GaN layer 5 while forming the i-AlGaN layer 7 to be defined as, for example, a re-growth of the compound semiconductor, the diffusion of the Mg ions serving as a p-type impurity into the channel side (e.g., the side of the electron supply layer 4) is stopped in the i-GaN layer 21. As a result, the Mg ions are suppressed from being diffused into the electron supply layer 4 and the electron transit layer 3, thereby suppressing an increase in the on resistance (Ron) resulting from the diffusion of the Mg ions as a p-type impurity.

### Third Exemplary Embodiment

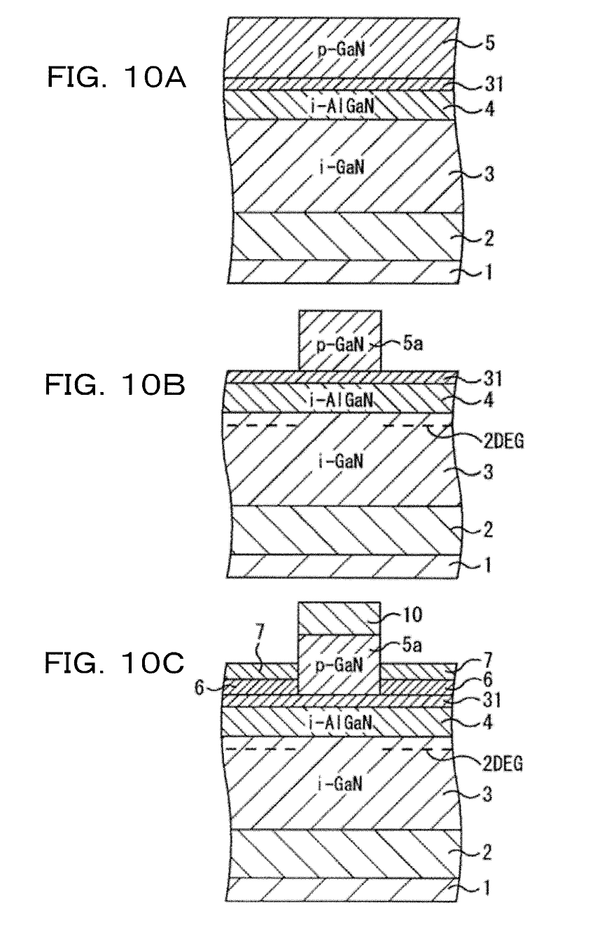

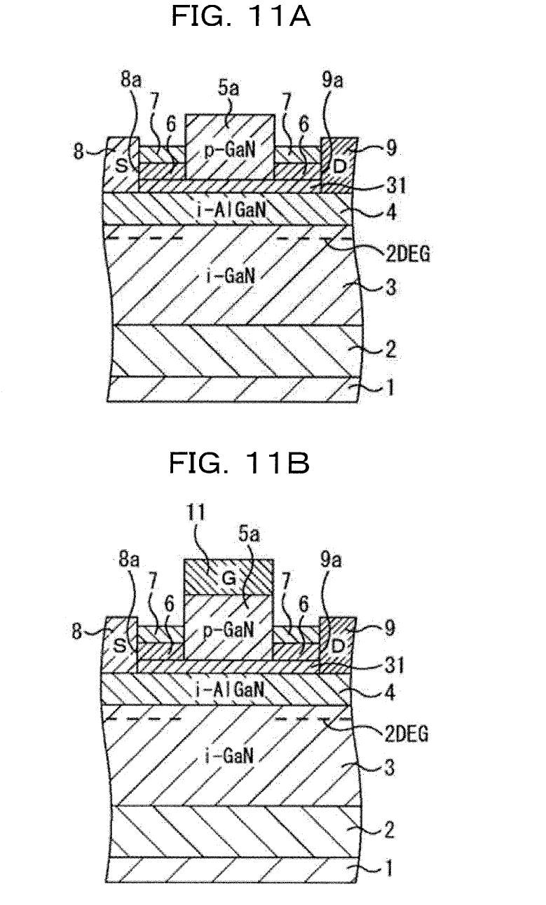

The present embodiment discloses a configuration and a manufacturing method of an AlGaN/GaN.HEMT in the same manner as in the first exemplary embodiment, but is different from the first exemplary embodiment in that an AlN layer is provided between an electron supply layer and a p-type GaN layer. Meanwhile, the same numerals are given to the same constituent members as those in the first exemplary embodiment, and the detailed description thereof will be omitted. FIGS. 10A to 10C and 11A to 11B are schematic cross-sectional views illustrating a manufacturing method of the AlGaN/GaN.HEMT according to a third exemplary embodiment in a process sequence.

First, as illustrated in FIG. 10A, a buffer layer 2, an electron transit layer 3, an electron supply layer 4, an AlN layer 31, and a p-type GaN layer 5 are sequentially formed on, for example, a SiC substrate 1 serving as a growth substrate. Specifically, each of the following compound semiconductors is grown under a reduced pressure atmosphere in the growth conditions described in the first exemplary embodiment by an MOVPE method. Alternatively, for example, an MBE method may be used instead of the MOVPE method.

On the SiC substrate 1, an AlN layer with a thickness of approximately 100 nm, an i-GaN layer with a thickness of approximately 3 μm, an i-AlGaN layer with a thickness of approximately 20 nm, an AlN layer with a thickness of approximately 2 nm, and a p-GaN layer with a thickness of approximately 80 nm are sequentially grown. In the growth of the AlN layer, a mixed gas of the TMAI gas and the NH₃ gas is used as a raw material gas. In the growth of the i-GaN layer, a mixed gas of the TMG gas and the NH₃ gas is used as a raw material gas. In the growth of the i-AlGaN layer, a mixed gas of the TMG gas, the TMAI gas, and the NH₃ gas is used as a raw material gas. In the growth of the p-GaN layer, a mixed gas of the TMG gas and the NH₃ gas is used as a raw material gas, and for example, the CpMg gas including, for example, the Mg ions serving as a p-type impurity may be introduced. By the above process, the buffer layer 2, the electron transit layer 3, the electron supply layer 4, the AlN layer 31, and the p-type GaN layer 5 are formed.

Subsequently, as illustrated in FIG. 10B, the p-type GaN layer 5 is etched. Specifically, a resist is applied on the p-type GaN layer 5, and UV rays are irradiated on a portion other than a gate electrode formation scheduled region by using a predetermined mask. Accordingly, a resist mask is formed, which covers the gate electrode formation scheduled region of the p-type GaN layer 5. The p-type GaN layer 5 is dry-etched by using the resist mask, and using a Cl₂-based etching gas. At this time, the AlN layer 31 serves as an etching stopper. Accordingly, the p-type GaN layer 5 remains only in the gate electrode formation scheduled region. The remaining p-type GaN layer 5 is defined as a p-type GaN layer 5a. The resist mask is removed by, for example, an ashing treatment or a chemical treatment.

Subsequently, as illustrated in FIG. 10C, an i-GaN layer 6 and an i-AlGaN layer 7 are sequentially formed on an AlN layer 31 at both sides of the p-type GaN layer 5a. Specifically, a predetermined resist mask is formed first, and for example, a SiO₂ layer is deposited thereon by, for example, a CVD method, so as to form a mask layer 10 which covers the top of the p-type GaN layer 5a. Subsequently, the i-GaN layer with a thickness of approximately 10 nm and the i-AlGaN layer with a thickness of approximately 10 nm are sequentially grown on the AlN layer 31 under a reduced pressure atmosphere by the MOVPE method. Accordingly, an i-GaN layer 6 and an i-AlGaN layer 7 are formed. The i-AlGaN layer 7 is made of i-Al_{0.2}Ga_{0.8}N with an Al composition ratio of, for example, 0.2. The mask layer 10 is removed by, for example, a chemical treatment.

The AlN layer 31 is an example of the fifth layer to be formed between the electron supply layer 4 as an example of the second layer and the p-type GaN layer 5a. The fifth layer is a compound semiconductor layer with a band gap larger than the band gap of the third layer, and the present embodiment utilizes the AlN layer 31 with a band gap larger than the band gap of the i-GaN layer 6 as an example of the third layer.

Subsequently, a device isolation structure is formed. Specifically, for example, argon (Ar) is implanted into a device isolation region at the upper side of the SiC substrate 1. As a result, the device isolation structure is formed at surface layer portions of the i-AlGaN layer 7, the i-GaN layer 6, the AlN layer 31, the electron supply layer 4, the electron transit layer 3, the buffer layer 2, and the SiC substrate 1. By the device isolation structure, an active region is defined on the i-AlGaN layer 7. Alternatively, the device isolation may be performed using, for example, an STI method instead of the aforementioned implanting method.

Subsequently, as illustrated in FIG. 11A, a source electrode 8 and a drain electrode 9 are formed. Specifically, electrode recesses 8a and 9a are formed first at the electrode formation scheduled positions for the source electrode and the drain electrode in the surface of the i-AlGaN layer 7. A resist is applied on an exposed surface including the surface of the i-AlGaN layer 7. The resist is processed by the lithography process and openings are formed in the resist, which expose the surface of the i-AlGaN layer 7 corresponding to the electrode formation scheduled positions. By the above process, a resist mask having the openings is formed.

Using this resist mask, the electrode formation scheduled positions of the i-AlGaN layer 7, the i-GaN layer 6, and the AlN layer 31 are dry-etched and removed until the surface of the electron supply layer 4 is exposed. Accordingly, the electrode recesses 8a and 9a are formed, which expose the electrode formation scheduled positions of the surface of the electron supply layer 4. For example, a Cl₂ gas is used as an etching gas. Meanwhile, the electrode recesses 8a and 9a may be formed by etching to the middle of the i-AlGaN layer 7, or may be formed by etching beyond the surface of the electron supply layer 4. The resist mask is removed by, for example, an ashing treatment.

A resist mask for forming the source electrode and the drain electrode is formed. Here, for example, a two-layer resist with an eaves structure is used, which is suitable for a vapor deposition method and a lift-off method. This resist is applied on an exposed surface including the surface of the i-AlGaN layer 7, and openings for exposing the electrode recesses 8a and 9a are formed. By the above process, a resist mask having the openings is formed.

Using this resist mask, for example, the Ti/Al layer is deposited as an electrode material by, for example, a vapor deposition method, on the resist mask including the inner portion of the openings for exposing the electrode recesses 8a and 9a. The thickness of the Ti layer is set to approximately 20 nm, and the thickness of the Al layer is set to approximately 200 nm. The resist mask and the Ti/Al layer deposited thereon are removed by, for example, the lift-off method. Thereafter, the SiC substrate 1 is thermally treated at a temperature of approximately 400° C. to 1,000° C., for example, approximately 600° C., for example, in a nitrogen atmosphere, so as to bring the remaining Ti/Al into ohmic contact with the electron supply layer 4. As long as an ohmic contact can be obtained with the electron supply layer 4 of the Ti/Al layer, the heat treatment may not be necessary. By the above process, the source electrode 8 and the drain electrode 9 are formed such that the electrode recesses 8a and 9a are embedded by a part of the electrode material.

Subsequently, as illustrated in FIG. 11B, a gate electrode 11 is formed. Specifically, a mask for forming the gate electrode is formed first. Here, for example, the SiN layer is deposited on the entire surface thereof by, for example, a CVD method, and dry-etching is performed by using, for example, a CF₄ gas, so as to form the openings which expose the top of the p-type GaN layer 5a on SiN. By the above process, a mask having the openings is formed.

Using this resist mask, for example, the Ni/Au layer is deposited as an electrode material by, for example, a vapor deposition method, on the mask including the inner portion of the openings for exposing the top of the p-type GaN layer 5a. The thickness of the Ni layer is set to approximately 30 nm, and the thickness of the Au layer is set to approximately 400 nm. The mask and the Ni/Au layer deposited thereon are removed by, for example, the lift-off method. The mask may also be used as a protective film without being removed. By the above process, a gate electrode 11 is formed on the p-type GaN layer 5a.

Thereafter, going through various processes such as forming an interlayer dielectric, forming wirings connected to the source electrode 8, the drain electrode 9, and the gate electrode 11, forming the passivation film of the upper layer, and forming a connection electrode which is exposed to the surface at the outermost side, the AlGaN/GaN.HEMT according to the present embodiment is formed.

As described above, in the present embodiment, it is possible to obtain a highly-reliable high withstand voltage AlGaN/GaN.HEMT which has neither deterioration in withstand voltage nor operation instability with a relatively simple configuration, and obtains a sufficiently large threshold voltage, and thus certainly realizes the normally-off state.

Furthermore, in the present embodiment, the AlN layer 31 is formed between the electron supply layer 4 and the p-type GaN layer 5a. That is, the AlN layer 31 is present immediately below the p-type GaN layer 5a. For that reason, during the activation annealing at the time of forming the p-type GaN layer 5 while forming the i-GaN layer 6 and the i-AlGaN layer 7 to be defined as, for example, a re-growth of the compound semiconductor, the diffusion of the Mg ions serving as a p-type impurity into the channel side (e.g., the side of the electron supply layer 4) is stopped in the AlN layer 31. Accordingly, the Mg ions are suppressed from being diffused into the electron supply layer 4 and the electron transit layer 3, thereby suppressing an increase in the on resistance (Ron) resulting from the diffusion of the Mg ions serving as a p-type impurity.

Furthermore, in the present embodiment, when the p-type GaN layer 5 is etched, the AlN layer 31 serves as an etching stopper layer, thereby making it possible to manufacture a device with a high precision.

### Fourth Exemplary Embodiment

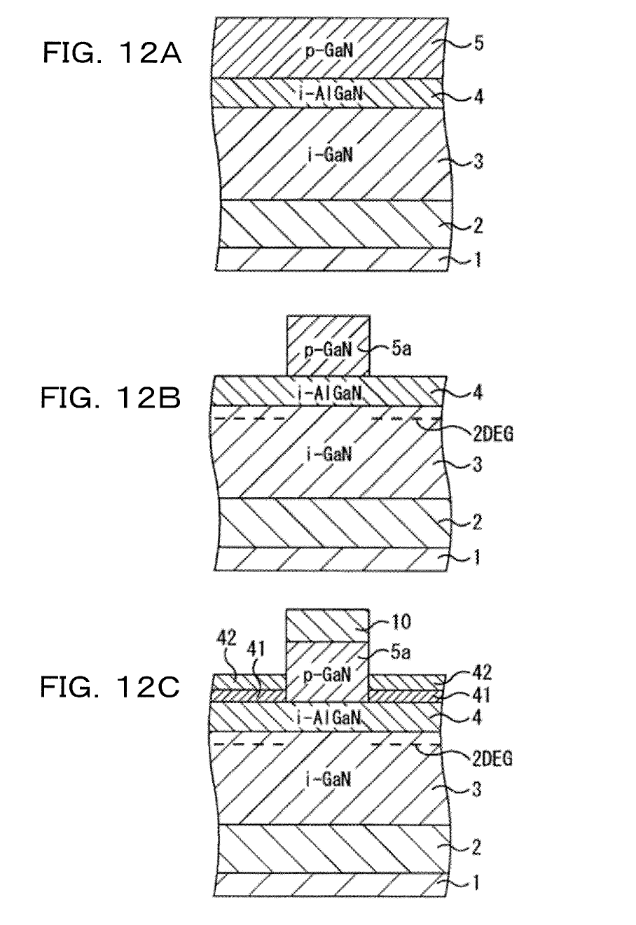

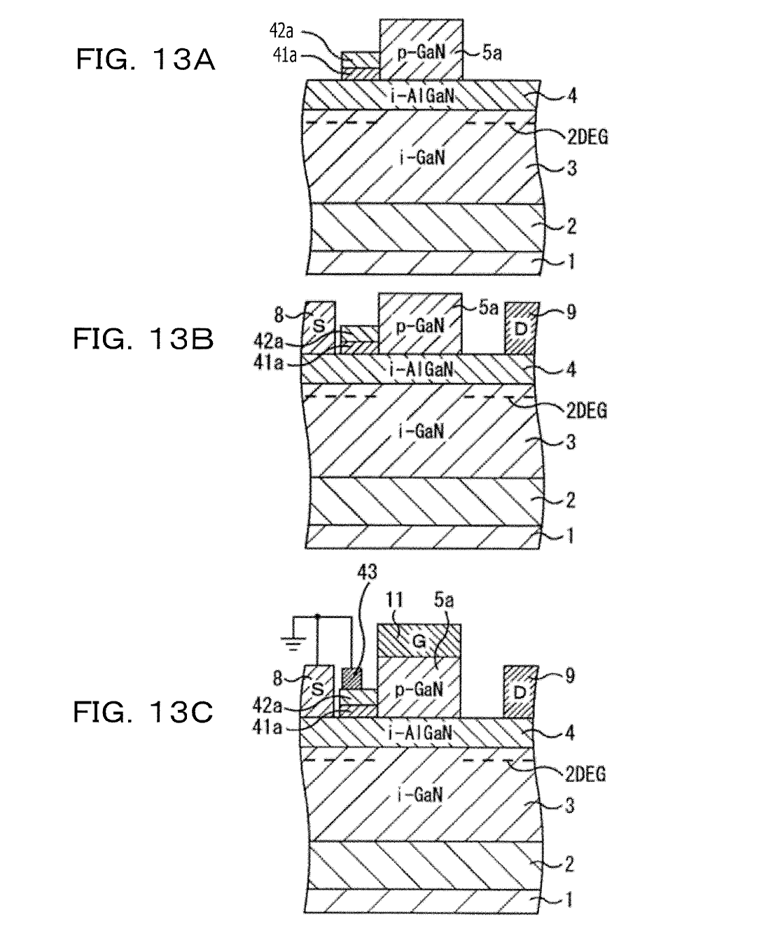

The present embodiment discloses a configuration and a manufacturing method of an AlGaN/GaN.HEMT in the same manner as in the first exemplary embodiment, but is different from the first exemplary embodiment in that the formation states of the i-GaN layer and the i-AlGaN layer on the electron supply layer are different from each other. Meanwhile, the same numerals are given to the same constituent members as those in the first exemplary embodiment, and the detailed description thereof will be omitted. FIGS. 12A to 12B and 13A to 13B are schematic cross-sectional views illustrating a manufacturing method of the AlGaN/GaN.HEMT according to a fourth exemplary embodiment in a process sequence.

As the same manner in the first exemplary embodiment of FIG. 2A, a buffer layer 2, an electron transit layer 3, an electron supply layer 4, and a p-type GaN layer 5 are sequentially formed first on, for example, a SiC substrate 1 serving as a growth substrate. The shape at this stage is illustrated in FIG. 12A. Subsequently, as the same manner in the first exemplary embodiment of FIG. 2B, the p-type GaN layer 5 is dry-etched, and is defined as the p-type GaN layer 5a. The shape at this stage is illustrated in FIG. 12B.

Subsequently, as illustrated in FIG. 12C, an i-GaN layer 41 and an i-AlGaN layer 42 are sequentially formed on an electron supply layer 4 at both sides of the p-type GaN layer 5a. Specifically, a predetermined resist mask is formed first, and for example, SiO₂ is deposited thereon by, for example, a CVD method, so as to form a mask layer 10 which covers the top of the p-type GaN layer 5a. Subsequently, the i-GaN layer with a thickness of approximately 10 nm and the i-AlGaN layer with a thickness of approximately 10 nm are sequentially grown on the electron supply layer 4 under a reduced pressure atmosphere by the MOVPE method. As a result, an i-GaN layer 41 and an i-AlGaN layer 42 are formed. The i-AlGaN layer 42 is made of i-Al_{0.2}Ga_{0.8}N with an Al composition ratio of, for example, 0.2. The mask layer 10 may be removed by, for example, a chemical treatment.

Subsequently, as illustrated in FIG. 13A, the i-GaN layer 41 and the i-AlGaN layer 42 are etched. Specifically, a resist is applied on the entire surface thereof, the resist is then processed by the lithography process, and thus a resist mask is formed, which covers a predetermined portion of the AlGaN layer 42. The i-AlGaN layer 42 and the i-GaN layer 41 are dry-etched by using the resist mask, and using a chlorine-based gas (e.g., a CF₄ gas). Accordingly, the i-GaN layer 41 and the i-AlGaN layer 42 are left, so as to be in contact with one side of the p-type GaN layer 5a only at the source electrode formation scheduled position side of the p-type GaN layer 5a. The remaining i-GaN layer 41 and i-AlGaN layer 42 are defined as the i-GaN layer 41a and the i-AlGaN layer 42a. The resist mask is removed by, for example, an ashing treatment or a chemical treatment.

Subsequently, a device isolation structure is formed. Specifically, for example, argon (Ar) ions are implanted into a device isolation region at an upper side of the SiC substrate 1. As a result, the device isolation structure is formed at surface layer portions of the i-AlGaN layer 42, the i-GaN layer 41, the electron supply layer 4, and the electron transit layer 3. By the device isolation structure, an active region is defined on the i-AlGaN layer 42. Alternatively, the device isolation may be performed using, for example, an STI method instead of the aforementioned implanting method.

Subsequently, a source electrode 8 and a drain electrode 9 are formed as illustrated in FIG. 13B. Specifically, a resist mask for forming the source electrode and the drain electrode is formed first. Here, for example, a two-layer resist with an eaves structure is used, which is suitable for a vapor deposition method and a lift-off method. This resist is applied on the entire surface thereof, and each opening is formed, which exposes the electrode formation scheduled positions of the source electrode and the drain electrode of the surface of the electron supply layer 4. By the above process, a resist mask having the openings is formed.

Using this resist mask, for example, the Ti/Al layer is deposited as an electrode material by, for example, a vapor deposition method, on the resist mask including the inner portion of each opening for exposing the electrode formation scheduled positions. The thickness of the Ti layer is set to approximately 20 nm, and the thickness of Al is set to approximately 200 nm. The resist mask and the Ti/Al layer deposited thereon are removed by, for example, the lift-off method. Thereafter, the SiC substrate 1 is thermally treated at a temperature of approximately 400° C. to 1,000° C., for example, approximately 550° C., for example, in a nitrogen atmosphere, so as to bring the remaining the Ti/Al layer into an ohmic contact with the electron supply layer 4. As long as an ohmic contact can be obtained with the electron supply layer 4 of the Ti/Al layer, the heat treatment may not be necessary. By the above process, a source electrode 8 and a drain electrode 9 are formed. Here, the source electrode may be formed to be spaced apart from the i-GaN layer 41 and the i-AlGaN layer 42.

Subsequently, as illustrated in FIG. 13C, a gate electrode 11 and a connection electrode 43 are formed. Specifically, a mask for forming the gate electrode and the connection electrode is formed first. Here, for example, SiN is deposited on the entire surface thereof by, for example, a CVD method, and dry-etching is performed by using, for example, a CF₄ gas, so as to form openings which expose a part of the top of the p-type GaN layer 5a and the top of the i-AlGaN layer 42 on SiN. By the above process, a mask having the openings is formed.

Using the mask, for example, the Ni/Au layer is deposited as an electrode material by, for example, a vapor deposition method, on the mask including the inner portion of the openings for exposing the top of the p-type GaN layer 5a and the inner portion of the openings for exposing a part of the top of the i-AlGaN layer 42. The thickness of the Ni layer is set to approximately 30 nm, and the thickness of the Au layer is set to approximately 400 nm. The mask and the Ni/Au layer deposited thereon are removed by, for example, the lift-off method. The mask may also be used as a protective film without being removed. By the above process, a gate electrode 11 is formed on the p-type GaN layer 5a, and a connection electrode 43 which is electrically connected to the i-AlGaN layer 42 is formed on the top of the i-AlGaN layer 42.

Thereafter, going through various processes such as forming an interlayer dielectric, forming wirings connected to the source electrode 8, the drain electrode 9, the gate electrode 11, and the connection electrode 43, forming the protective film of the upper layer, and forming a connection electrode which is exposed to the outermost surface thereof, the AlGaN/GaN.HEMT according to the present embodiment is formed. In the present embodiment, the connection electrode 43 is electrically connected to the source electrode 8 and grounded together, as illustrated in FIG. 13C.

As described above, in the present embodiment, it is possible to obtain a highly-reliable high withstand voltage AlGaN/GaN.HEMT which has neither deterioration in withstand voltage nor operation instability with a relatively simple configuration, and obtains a sufficiently large threshold voltage, and thus certainly realizes the normally-off state.

### Fourth Exemplary Embodiment

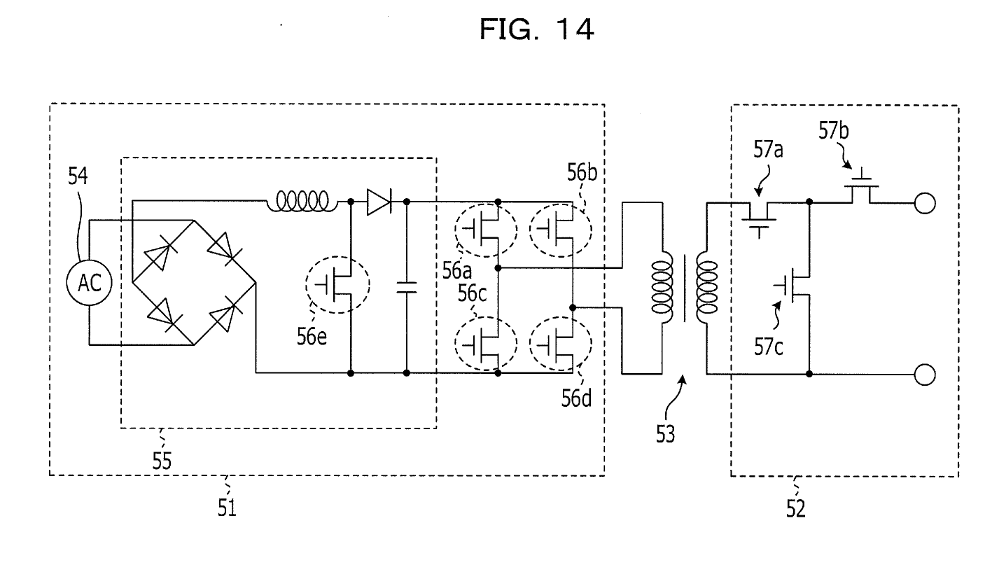

The present embodiment discloses a power supply to which one AlGaN/GaN.HEMT selected from the first to third exemplary embodiments is applied. FIG. 14 is a connection diagram illustrating a schematic configuration of a power supply according to a fourth exemplary embodiment.

The power supply according to the present embodiment is configured to include a high-voltage primary side circuit 51, a low-voltage secondary side circuit 52, and a transformer 53 disposed between the primary side circuit 51 and the secondary side circuit 52. The primary side circuit 51 includes an alternating-current power source 54, a so-called bridge rectifier circuit 55, and a plurality of switching devices 56a, 56b, 56c, and 56d (e.g., four switching devices). Further, the bridge rectifier circuit 55 has a switching device 56e. The secondary side circuit 22 includes a plurality of switching devices 57a, 57b, and 57c (e.g., three switching devices).

In the present embodiment, the switching devices 56a, 56b, 56c, 56d, and 56e of the primary side circuit 51 are made of one AlGaN/GaN.HEMT selected from the first to third exemplary embodiments. Meanwhile, the switching devices 57a, 57b, and 57c of the secondary side circuit 52 are made of a usual MIS.FET using silicon.

In the present embodiment, a highly-reliable high withstand voltage AlGaN/GaN.HEMT is applied to a high-voltage circuit, in which the AlGaN/GaN.HEMT has neither deterioration in withstand voltage nor operation instability with a relatively simple configuration, and obtains a sufficiently large threshold voltage, and thus certainly realizes the normally-off state. As a result, a highly-reliable power supply circuit with high power is realized.

### Fifth Embodiment

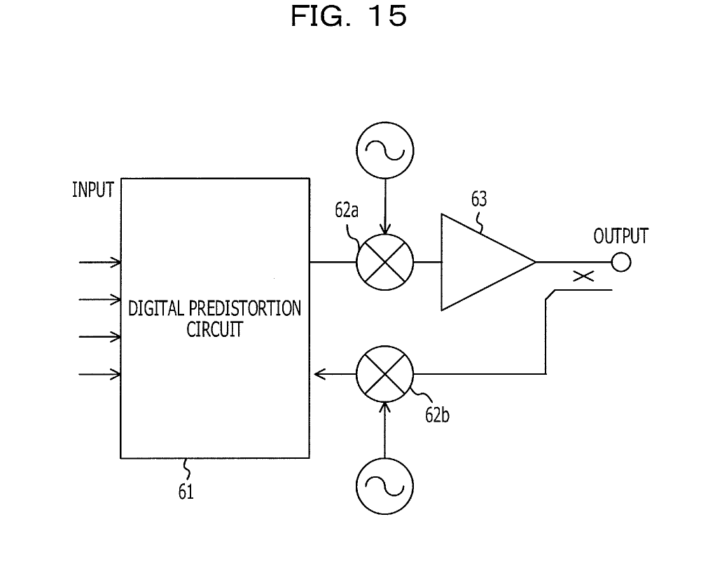

The present embodiment discloses a high frequency amplifier to which one AlGaN/GaN.HEMT selected from the first to third exemplary embodiments is applied. FIG. 15 is a connection diagram illustrating a schematic configuration of a high frequency amplifier according to a fifth embodiment.

The high frequency amplifier according to the present embodiment includes a digital predistortion circuit 61, mixers 62a and 62b, and a power amplifier 63. The digital predistortion circuit 61 offsets the non-linear strains of input signals. The mixer 62a mixes the input signals, whose non-linear strains have been offset, with AC signals. The power amplifier 63 amplifies the input signals that have been mixed with the AC signals, and has one AlGaN/GaN.HEMT selected from first to third exemplary embodiments. Meanwhile, FIG. 15 illustrates a configuration in which signals on the output side may be mixed with AC signals by the mixer 62b and sent to the digital predistortion circuit 61 by, for example, switching the switch.

In the present embodiment, a highly-reliable high withstand voltage AlGaN/GaN.HEMT is applied to a high frequency amplifier, in which the AlGaN/GaN.HEMT has neither deterioration in withstand voltage nor operation instability with a relatively simple configuration, and obtains a sufficiently large threshold voltage, and thus certainly realizes the normally-off state. As a result, a highly-reliable high frequency amplifier with a high withstand voltage is realized.

### Other Embodiments

The first to fifth embodiments exemplify the AlGaN/GaN.HEMT as a compound semiconductor device. As for the compound semiconductor device, the following HEMT may be applied in addition to the AlGaN/GaN.HEMT.

Another Example 1 of HEMT

The present example discloses an InAlN/GaN.HEMT as a compound semiconductor device. InAlN and GaN are compound semiconductors whose lattice constant may be made close by the compositions thereof. In this case, in the aforementioned first to fifth embodiments, the electron transit layer serving as the first layer of the compound semiconductor is formed of i-GaN, and the electron supply layer as the second layer thereof is formed of i-InAlN. Further, the third layer and the fourth layer (and the fifth layer) are appropriately formed in order to satisfy the aforementioned Equations (1), (2), and (3) simultaneously. In this case, piezoelectric polarization barely occurs, and thus the two-dimensional electron gas is mainly generated by spontaneous polarization of the InAlN.

According to the present example, as in the above-described AlGaN/GaN.HEMT, there is realized a highly-reliable high withstand voltage InAlN/GaN.HEMT, which has neither deterioration in withstand voltage nor operation instability with a relatively simple configuration, and obtains a sufficiently large threshold voltage, and thus certainly realizes the normally-off state.

Another Example 2 of HEMT

The present example discloses an InAlGaN/GaN.HEMT as a compound semiconductor device. GaN and InAlGaN are compound semiconductors where the latter may have a smaller lattice constant than the former by the compositions thereof. In this case, in the aforementioned first to fifth embodiments, the electron transit layer as the first layer of the compound semiconductor is formed of i-GaN, and the electron supply layer as the second layer thereof is formed of i-InAlGaN. In addition, the third layer and the fourth layer (and the fifth layer) are appropriately formed in order to satisfy the aforementioned Equations (1), (2), and (3) simultaneously.

According to the present example, as in the above-described AlGaN/GaN.HEMT, there is realized a highly-reliable high withstand voltage InAlGaN/GaN.HEMT, which has neither deterioration in withstand voltage nor operation instability with a relatively simple configuration, and obtains a sufficiently large threshold voltage, and thus certainly realizes the normally-off state.

According to the various aforementioned aspects, there is realized a highly-reliable high withstand voltage compound semiconductor device which has neither deterioration in withstand voltage nor operation instability, and obtains a sufficiently large threshold voltage, and thus certainly realizes the normally-off state with a relatively simple configuration.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has(have) been described in detail, it should be understood that the various changes, substitutions, and alterations could be made hereto without departing from the spirit and scope of the invention.

What is claimed is:

1. A compound semiconductor device comprising:
a first compound semiconductor layer;
a second compound semiconductor layer formed on an upper side of the first compound semiconductor layer and having a band gap larger than the band gap of the first compound semiconductor layer;
a p-type third compound semiconductor layer formed on an upper side of the second compound semiconductor layer;
an electrode formed on an upper side of the second compound semiconductor layer through the third compound semiconductor layer;
a fourth compound semiconductor layer formed so as to be in contact with the third compound semiconductor layer at an upper side of the second compound semiconductor layer and having a band gap smaller than the band gap of the second compound semiconductor layer; and
a fifth compound semiconductor layer formed so as to be in contact with the third compound semiconductor layer at an upper side of the fourth compound semiconductor layer and having a band gap larger than the band gap of the fourth compound semiconductor layer.

2. The compound semiconductor device of claim 1, wherein the fourth compound semiconductor layer and the fifth compound semiconductor layer are formed at a side surface of the third compound semiconductor layer.

3. The compound semiconductor device of claim 2, further comprising:
a sixth compound semiconductor layer formed between the second compound semiconductor layer and the third compound semiconductor layer and having a band gap larger than the band gap of the fourth compound semiconductor layer.

4. The compound semiconductor device of claim 1, wherein the fourth compound semiconductor layer is formed between the second compound semiconductor layer and the third compound semiconductor layer, and the fifth compound semiconductor layer is formed at a side surface of the third compound semiconductor layer.

5. The compound semiconductor device of claim 4, wherein a part or an entire of the fourth compound semiconductor layer becomes p-type in a region where the fourth compound semiconductor layer is disposed below the third compound semiconductor layer.

6. The compound semiconductor device of claim 1, wherein the fourth compound semiconductor layer and the fifth compound semiconductor layer are formed only at one side surface of the third compound semiconductor layer.

7. The compound semiconductor device of claim 6, further comprising:
a connection electrode electrically connected to the fifth compound semiconductor layer.

8. A method for manufacturing a compound semiconductor device, the method comprising:
providing a first compound semiconductor layer having a band gap;
forming a second compound semiconductor layer having a band gap larger than the band gap of the first compound semiconductor layer on an upper side of the first compound semiconductor layer;
forming a p-type third compound semiconductor layer on an upper side of the second compound semiconductor layer;
forming an electrode on an upper side of the second compound semiconductor layer through the third compound semiconductor layer;
forming a fourth compound semiconductor layer having a band gap smaller than the band gap of the second compound semiconductor layer so as to be in contact with the third compound semiconductor layer at an upper side of the second compound semiconductor layer; and
forming a fifth compound semiconductor layer having a band gap larger than the band gap of the fourth compound semiconductor layer so as to be in contact with the third compound semiconductor layer at an upper side of the fourth compound semiconductor layer.

9. The method of claim 8, wherein the fourth compound semiconductor layer and the fifth compound semiconductor layer are formed at a side surface of the third compound semiconductor layer.

10. The method of claim 9, further comprising:
forming a sixth compound semiconductor layer having a band gap larger than the band gap of the fourth compound semiconductor layer between the second compound semiconductor layer and the third compound semiconductor layer.

11. The method of claim 8, wherein the fourth compound semiconductor layer is formed between the second compound semiconductor layer and the third compound semiconductor layer, and the fifth compound semiconductor layer is formed at a side surface of the third compound semiconductor layer.

12. The method of claim 11, wherein a part or whole of the fourth compound semiconductor layer becomes p-type in a region where the fourth compound semiconductor layer is disposed below the third compound semiconductor layer.

13. The method of claim 8, wherein the fourth compound semiconductor layer and the fifth compound semiconductor layer are formed only at one side surface of the third compound semiconductor layer.

14. The method of claim 13, further comprising:
forming a connection electrode on the fifth compound semiconductor layer.

15. A power supply circuit comprising: a transformer, and a low-voltage circuit and a high-voltage circuit across the transformer,
wherein the high-voltage circuit has a transistor, and
the transistor comprises:
a first compound semiconductor layer;
a second compound semiconductor layer formed on an upper side of the first compound semiconductor layer and having a band gap larger than the band gap of the first compound semiconductor layer;
a conductive p-type third compound semiconductor layer formed on an upper side of the second compound semiconductor layer;
an electrode formed on an upper side of the second compound semiconductor layer through the third compound semiconductor layer;
a fourth compound semiconductor layer formed so as to be in contact with the third compound semiconductor layer at an upper side of the second compound semiconductor layer and having a band gap smaller than the band gap of the second compound semiconductor layer; and
a fifth compound semiconductor layer formed so as to be in contact with the third compound semiconductor layer at an upper side of the fourth compound semiconductor layer and having a band gap larger than the band gap of the fourth compound semiconductor layer.

16. A high frequency amplifier which amplifies and outputs a high frequency voltage input, the high frequency amplifier comprising:
a transistor,
wherein the transistor comprises:
a first compound semiconductor layer;
a second compound semiconductor layer formed on an upper side of the first compound semiconductor layer and having a band gap larger than the band gap of the first compound semiconductor layer;
a conductive p-type third compound semiconductor layer formed on an upper side of the second compound semiconductor layer;
an electrode formed on an upper side of the second compound semiconductor layer through the third compound semiconductor layer;
a fourth compound semiconductor layer formed so as to be in contact with the third compound semiconductor layer at an upper side of the second compound semiconductor layer and having a band gap smaller than the band gap of the second compound semiconductor layer; and
a fifth compound semiconductor layer formed so as to be in contact with the third compound semiconductor layer at an upper side of the fourth compound semiconductor layer and having a band gap larger than the band gap of the fourth compound semiconductor layer.
